(19) United States
(12) Patent Application Publication
(10) Pub. No.: US 2006/0145357 A1
(43) Pub. Date: Jul. 6, 2006

(54) Flip chip package structure

(75) Inventors: Tsung-Lung Chen, Fongshan City (TW); Geng Shin Shen, Tainan City (TW)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(73) Assignees: ChipMos Technologies Inc.; ChipMos Technologies (Bermuda) LTD

(21) Appl. No.: 11/202,685

(22) Filed: Aug. 12, 2005

(30) Foreign Application Priority Data
Dec. 31, 2004 (TW) 093141899

(51) Int. Cl. H01L 23/495

(52) U.S. Cl. 257/778

(57) ABSTRACT

The invention provides a flip chip package structure. The flip chip package structure includes a substrate, a flip chip, a plurality of bumps, a first sealing material, and a second sealing material. The substrate has an upper surface and a plurality of pads formed on the upper surface. The flip chip has an active surface. Each of the bumps corresponds to one of the pads of the substrate, and the active surface of the flip chip is electrically connected and is attached to the upper surface of the substrate by the bumps. The first sealing material is coated between the flip chip and the substrate so as to fix the flip chip on the substrate. The second sealing material is coated to cover the first sealing material.

### BACKGROUND OF THE INVENTION

1. Field of the Invention

The present invention relates to a flip chip package structure.

2. Description of the Prior Art

Flip chip is a packaging technology to connect a chip with a substrate. The chip is flipped over in the packaging process to connect its junction point to the pads of the substrate. Owing to the prime cost and the factors in the manufacturing process, the products utilizing flip chip technology are divided into two kinds: one is the flip chip on board (FCOB) for low I/O frequency, and the other is the flip chip in package (FCIP) for high I/O frequency.

Flip chip technology is utilized in many products such as computers, PCMCIA cards, military facilities, individual communication products, timepieces, and LCDs. There are two advantages to employ flip chip: first, the transmission distance of the electronic signals between the chip and the substrate can be lowered, so as to apply to the high-speed element packaging; second, the packaging size of the chip is reduced to reach chip-size packaging.

Flip-chip-on-film package is to reverse a high efficiency chip on a flexible substrate, so it can be utilized in electronic devices with small volume such as drive IC, mobile phones, and laptops.

In the flip chip package, an under-filling material is usually stuffed into a gap between the chip and the substrate for increasing the reliability of the products. The under-filling material is formed by the following conventional methods. One of the methods is to spread the under-filling material around the chip in L-shape, U-shape, or I-shape, utilizing the capillarity effect to drift the material into the gaps between the chip and the substrate. However, the under-filling material formed by this method often contains air bubbles inside.

The other way is to utilize a non-conductive paste to fix the chip and the substrate and to reduce the sealing time. Please refer to FIG. 1; FIG. 1 is a cross-sectional view showing a conventional flip chip package structure 1. As shown in FIG. 1, the method is to spread the non-conductive paste 14 on the substrate 18, and a chip 10 is then reversed and is connected firmly to the substrate 18 as the non-conductive paste 14 solidifies and contracts. However, this method employs the chip 10 to press down on the non-conductive paste 14, such that the spreading of the non-conductive paste 14 is not even, and the bumps 12 formed on the chip 10 are easily exposed. Furthermore, the non-conductive paste 14 used in this method is costly.

Accordingly, the invention provides a flip chip package structure that can solve the problems mentioned above and can increase the reliability of the flip chip package.

### SUMMARY OF THE INVENTION

According to a first preferred embodiment of the invention, the flip chip package structure includes a substrate, a flip chip, a plurality of bumps, a first sealing material, and a second sealing material. The substrate has an upper surface and a plurality of pads formed on the upper surface. The flip chip has an active surface. Each of the bumps corresponds to one of the pads of the substrate, and the active surface of the flip chip is electrically connected and is attached to the upper surface of the substrate by the bumps. The first sealing material is coated between the flip chip and the substrate, so as to fix the flip chip on the substrate. The second sealing material is coated to cover the first sealing material and the bumps.

The flip chip package structure provided by the invention utilizes a second sealing material to seal up the first sealing material which is between the flip chip and the substrate, so as to avoid the bumps being exposed and to increase the reliability of the flip chip package structure. Besides, a low-cost material can be used as the first sealing material in the invention to decrease the prime cost.

The advantage and spirit of the invention may be understood by the following recitations together with the appended drawings.

### BRIEF DESCRIPTION OF THE APPENDED DRAWINGS

FIG. 1 is a cross-sectional view showing a conventional flip chip package structure.

FIG. 2 is a cross-sectional view showing the flip chip package structure according to the invention.

FIG. 3A to FIG. 3C illustrate the manufacturing process of the flip chip package structure according to the invention.

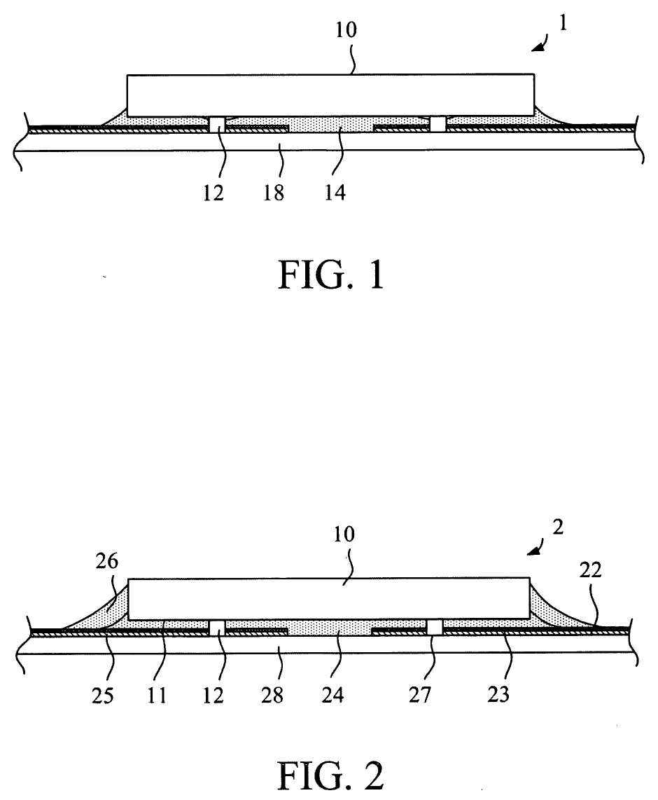

### DETAILED DESCRIPTION OF THE INVENTION

Please refer to FIG. 2; FIG. 2 is a cross-sectional view showing the flip chip package structure according to the invention. As shown in FIG. 2, the flip chip package structure 2 includes a substrate 28, a flip chip 10, a plurality of bumps 12, a first sealing material 24, and a second sealing material 26. In this embodiment, the substrate 28 is a flexible printing circuit board made of polyimide, polyester or the like. The substrate 28 has an upper surface 22, a plurality of pads 27 formed on the upper surface 22, and a lead layer 25. The lead layer 25 is formed on the upper surface 22 and is connected to the pads 27. An anti-oxidant conductive film 23 is formed on the surface of the pads 27 and the lead layer 25, and it is composed of nickel, aluminum, or tin; consequently, the pads 27 and the lead layer 25 do not have to be covered by a solder mask like the conventional way.

The flip chip 10 has an active surface 11. In this embodiment, the bumps 12 are gold bumps. Each of the bumps 12 corresponds to one of the pads 27 of the substrate 28. The flip chip 10 relies on the bumps 12 of the active surface 11, which faces down, to electrically connect and to attach, by a eutectic bonding process or an ultrasonic bonding process, to the upper surface 22 of the substrate 28. The bumps 12 are formed on the active surface 11 of the flip chip 10 or on the pads 27, and they bond with the pads 27 of the substrate 28 in an interatomic bonding manner.

The first sealing material 24 can be a non-conductive paste (NCP) or a thermosetting material. The first sealing material 24 is coated between the flip chip 10 and the substrate 28, so as to fix the flip chip 10 on the substrate 28. The second sealing material 26 can be an under-filling material or a waterproof material. The second sealing material 26 is coated around the flip chip 10 to cover the first sealing material 24 and the bumps 12.

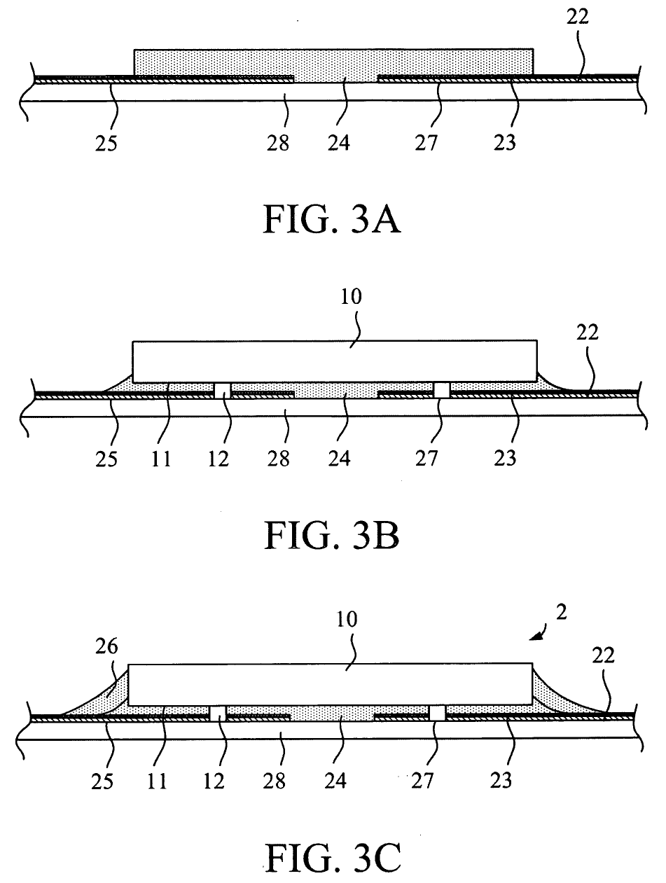

Referring to FIG. 3A to FIG. 3C, FIG. 3A to FIG. 3C illustrate the manufacturing process of the flip chip package structure according to the invention. A substrate 28 and a flip chip 10 are provided. The substrate 28 has an upper surface 22 and a plurality of pads 27 formed on the upper surface 22. The flip chip 10 has an active surface 11, and in this embodiment, the plurality of bumps 12 are formed on the flip chip 10.

First, please refer to FIG. 3A. As shown in FIG. 3A, a first sealing material 24 is coated on the upper surface 22 of the substrate 28. The first sealing material 24 can be a non-conductive paste or a thermosetting material. As shown in FIG. 3B, the flip chip 10 is then reversed with the active surface 11 facing down, and it relies on the bumps 12 to go through the first sealing material 24 to connect with the pads 27 on the substrate 28. The first sealing material 24 is solidified, so as to fix the flip chip 10 on the substrate 28. Because the first sealing material 24 is thermosetting and has contractibility, the bumps 12 and the pads 27 can contact tightly and can maintain electrical connection. Also, the bumps 12 can bond with the pads 27 of the substrate 28 in an interatomic bonding manner by a eutectic bonding process or an ultrasonic bonding process. Some of the bumps may not be covered completely, and a second sealing material 26 is therefore coated around the circumference of the flip chip 10 to cover the first sealing material 24 and the bumps 12, so as to accomplish the flip chip package structure 2 as shown in FIG. 3C. The second sealing material 26 can be an under-filling material or a waterproof material.

As the steps mentioned above, the flip chip 10 is reversed with the active surface 11 facing down, and it relies on the bumps 12 of the active surface 11 to go through the first sealing material 24 to electrically connect with the pads 27. The first sealing material 24 may not be able to fill up the gap between the substrate 28 and the flip chip 10 because the spreading is not sufficient, so the active surface 11 of the flip chip 10 is not protected completely. Moreover, the bumps 12 and the lead layer 25 are not covered completely by first sealing material 24 and are exposed outside. Accordingly, the flip chip package structure 2 of the invention utilizes the second sealing material 26 to fill up the gap between the substrate 28 and the flip chip 10, which is not filled up by the first sealing material 24, so as to protect the active surface 11 of the flip chip 10. Meanwhile, the second sealing material 26 can cover and seal the exposed portions of the bumps 12 and the lead layer 25 to increase reliability.

Furthermore, the exposed portions of the pads and the lead layer of the prior art have to be gilded for keeping the reliability of the flip chip package structure, so the prime cost is higher. The flip chip package structure 2 of the invention utilizes the first sealing material 24 and the second sealing material 26 to cover the pads 27 and the lead layer 25 and replaces gilding by forming an anti-oxidant conductive film 23 composed of low-cost materials such as nickel, aluminum, tin and the like on the lead layer 25. After coating the second sealing material 26 around the flip chip 10, the solidified first sealing material 24 is sealed up by the second sealing material 26. Therefore, low-cost material can be used as the first sealing material 24 to lower the prime cost.

The flip chip package structure of the invention can also be utilized in the flip chip package using hard substrate. The second sealing material such as a non-conductive paste is utilized to seal up the solidified first sealing material to decrease the possibility of exposing the bumps and to increase the reliability of the flip chip package structure.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A flip chip package structure, comprising:
a substrate having an upper surface and a plurality of pads formed on the upper surface;
a flip chip having an active surface;
a plurality of bumps, each of the bumps corresponding to one of the pads of the substrate, the flip chip electrically connecting and attaching to the pads of the substrate by the bumps;
a first sealing material coated between the flip chip and the substrate so as to fix the flip chip on the substrate; and
a second sealing material coated to cover the first sealing material.

2. The flip chip package structure of claim 1, wherein the bumps bond with the pads of the substrate in an interatomic bonding manner.

3. The flip chip package structure of claim 2, wherein the bumps bond with the pads of the substrate by a eutectic bonding process or an ultrasonic bonding process.

4. The flip chip package structure of claim 1, wherein the substrate further comprises a lead layer formed on the upper surface thereof and connected to the pads.

5. The flip chip package structure of claim 4, wherein the lead layer has an anti-oxidant conductive film thereon, and the anti-oxidant conductive film comprises nickel, aluminum, or tin.

6. The flip chip package structure of claim 1, wherein the bumps are formed on the active surface of the flip chip or on the pads.

7. The flip chip package structure of claim 1, wherein the bumps are gold bumps.

8. The flip chip package structure of claim 1, wherein the first sealing material is a thermosetting material.

9. The flip chip package structure of claim 1, wherein the first sealing material is a non-conductive paste (NCP).

10. The flip chip package structure of claim 1, wherein the second sealing material is an under-filling material.

11. The flip chip package structure of claim 1, wherein the second sealing material is coated around the flip chip.

12. The flip chip package structure of claim 1, wherein the second sealing material is waterproof.

13. The flip chip package structure of claim 1, wherein the substrate is a flexible printing circuit board.

14. The flip chip package structure of claim 1, wherein the second sealing material coated to cover the bumps.
